(19) United States
(12) Patent Application Publication
(10) Pub. No.: US 2023/0043166 A1
(43) Pub. Date: Feb. 9, 2023

(54) SEAL RING REINFORCEMENT

(71) Applicant: Taiwan Semiconductor Manufacturing Company, Ltd., Hsinchu (TW)

(72) Inventors: Yen Lian Lai, Hsinchu (TW); Chun Yu Chen, Hsinchu (TW)

(21) Appl. No.: 17/716,444

(22) Filed: Apr. 8, 2022

Related U.S. Application Data
(60) Provisional application No. 63/229,904, filed on Aug. 5, 2021.

(51) Int. Cl. H01L 23/58; H01L 23/00; H01L 21/71

(52) U.S. Cl. CPC H01L 23/585; H01L 23/562; H01L 23/564; H01L 21/71

(57) ABSTRACT

Integrated circuit (IC) chips and seal ring structures are provided. An IC chip according to the present disclosure includes an interconnect structure that includes a first metal line, a second metal line, a third metal line, a fourth metal line, and a fifth meal line extending along a first direction, a first group of lateral connectors disposed between the second metal line and the third metal line or between the fourth metal line and the fifth metal line, and a second group of lateral connectors disposed between the first metal line and the second metal line or between the third metal line and the fourth metal line.

### PRIORITY DATA

This application claims priority to U.S. Provisional Patent Application Ser. No. 63/229,904, filed Aug. 5, 2021, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor.

Due to the scaling down, the structures of the FinFETs or MBC transistors may be susceptible to damages due to mist ingress or stress during singulation. Seal structures have been implemented to protect semiconductor devices. While existing seal structures are generally satisfactory for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a top view of a substrate, according to one or more aspects of the present disclosure.

FIG. 2 illustrates a cross-sectional view of an interconnect structure disposed on the substrate in FIG. 1, according to one or more aspects of the present disclosure.

FIG. 3 illustrates a top view of an interconnect structure disposed on the substrate in FIG. 1, according to one or more aspects of the present disclosure.

FIG. 4 illustrates an enlarged fragmentary top view of a corner portion of the interconnect structure, according to one or more aspects of the present disclosure.

FIG. 5 illustrates an enlarged fragmentary top view of a portion of the interconnect structure disposed over a ring region of the substrate in FIG. 1, according to one or more aspects of the present disclosure.

FIG. 6 illustrates an enlarged fragmentary cross-sectional view of the portion of the interconnect structure in FIG. 5, according to one or more aspects of the present disclosure.

FIG. 7 illustrates an enlarged fragmentary cross-sectional view of the portion of the interconnect structure in FIG. 5, according to one or more aspects of the present disclosure.

FIG. 8 illustrates a flowchart of a method 300 for fabricating an interconnect structure, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed. For avoidance of doubts, the X, Y and Z directions in figures of the present disclosure are perpendicular to one another. Throughout the present disclosure, like reference numerals denote like features, unless otherwise excepted.

Seal structures are used to prevent semiconductor devices in an integrated circuit (IC) chip from being damaged due to mist ingress or stress during singulation of the IC chip. Multi-gate devices, such as FinFETs and MBC transistors, emerge as the industry moves toward smaller device nodes. While multi-gate transistors feature improved gate control and reduced short channel effects, they are not immune from damages from water and stress. In fact, due to their delicate dimensions and structures, they may be more prone to damages if not protected by adequate seal structures. Multi-gate devices are fabricated on a substrate and an interconnect structure is disposed over the substrate to functionally interconnect the multi-gate devices. Seal structures may be implemented in both the substrate and the interconnect structures. Seal structures in the interconnect structure may come in the form of metal lines in different metal layers. In some existing technologies, metal lines in metal layers closer to the substrate may have smaller dimensions that do not provide sufficient mechanical strength or stress absorption, both of which are considered as attributes of good seal ring structures.

The present disclosure provides an IC chip that includes stress absorption and reinforcement structures in its seal ring structure. According to embodiments of the present disclosure, the IC chip includes a substrate and an interconnect structure disposed on the substrate. The substrate includes a device region and a ring region surrounding the device region. The device region includes functional semiconductor devices and the ring region accommodate seal ring structures. The interconnect structure over the substrate also includes a device portion and a ring portion vertically corresponding to the device region and the ring region of the substrate, respectively. The device portion includes metal lines and vias to functionally interconnect the semiconductor devices in the device region. The ring portion accommodates seal ring structures. A portion of the ring portion includes a plurality of metal line loops, each of which goes completely around the device portion. Extending substantially parallel to one another, the plurality of metal line loops are laterally connected by a plurality of lateral connectors. The plurality of lateral connectors are aligned along a direction perpendicular to the longitudinal direction of the metal line loops. The lateral connectors increase the mechanical integrity of the metal line loops as a whole.

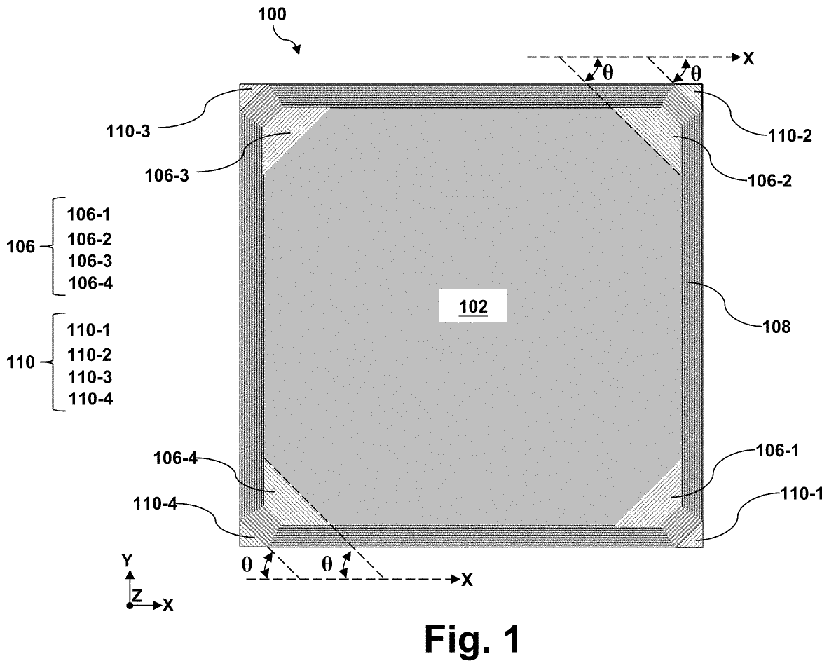

Reference is first made to FIG. 1, which includes a top view of a substrate 100. The substrate 100 includes a device region 102, a ring region 108 continuously surrounding the device region 102, four inner corner areas 106 disposed between outer corners of the device region 102 and inner corners of the ring region 108, four outer corner areas 110 around outer corners of the ring region 108. The inner corner areas 106 include a first inner corner area 106-1, a second inner corner area 106-2, a third inner corner area 106-3, and a fourth inner corner area 106-4. For ease of reference, the first inner corner area 106-1, the second inner corner area 106-2, the third inner corner area 106-3, and the fourth inner corner area 106-4 may be collectively or respectively referred to as inner corner areas 106. The outer corner areas 110 include a first outer corner area 110-1, a second outer corner area 110-2, a third outer corner area 110-3, and a fourth outer corner area 110-4. For ease of reference, the first outer corner area 110-1, the second outer corner area 110-2, the third outer corner area 110-3, and the fourth outer corner area 110-4 may be collectively or respectively referred to as outer corner areas 110. The inner corner areas 106, the ring region 108, and the outer corner areas 110 accommodate seal ring structures at the substrate level. The seal ring structures at the substrate level are fabricated alongside with functional semiconductor devices in the device region 102. While the seal ring structures outside the device region 102 may have different shapes or dimensions from those of the semiconductor devices inside the device region 102, their features may share identical or similar compositions.

The substrate 100, the device region 102, and the ring region 108 may be substantially rectangular when viewed along the Z direction from the top. Each of the inner corner areas 106 resembles an isosceles right triangle with the right-angle corner clipped off. In other words, each of the inner corner areas 106 may assume a shape of an isosceles trapezoid. Each of the outer corner areas 110 has a shape of a right isosceles triangle. Put differently, as shown in FIG. 1, the hypotenuse (or the base of the isosceles trapezoid) of each of the inner corner areas 106 or each of the outer corner areas 110 forms an acute angle θ with the X direction or the Y direction. The acute angle θ may be between about 40° or about 50°. In the depicted embodiment, the acute angle θ is at 45°. In FIG. 1, the device region 102 includes four cut-off corners that includes an edge parallel to the hypotenuse of the adjacent inner corner area 106. The ring region 108, while being largely rectangular in shape, is disposed between and engages the inner corner areas 106 and the device region 102. That is, the ring region 108 includes cut-off outer corners that correspond to the outer corner areas 110 and push-out inner corners that correspond to the four inner corner areas 106. As shown in FIG. 1, the ring region 108 extend continuously around the device region 102. In the depicted embodiment, both the device region 102 and the ring region 108 are octagonal, with the ring region 108 going around the device region 102.

In some embodiments, the substrate 100 may be a bulk silicon (Si) substrate. Alternatively, substrate 100 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. In some implementations, the substrate 100 includes one or more group III-V materials, one or more group II-VI materials, or combinations thereof. In still some instances, the substrate 100 is a semiconductor-on-insulator substrate, such as a silicon-on-insulator (SOI) substrate, a silicon germanium-on-insulator (SGOI) substrate, or a germanium-on-insulator (GeOI) substrate. In still some embodiments, the substrate 100 may be diamond substrate or a sapphire substrate.

Different regions of the substrate 100 may include various semiconductor structures, such as active regions, gate structures disposed over channel regions of the active regions, source/drain features disposed over source/drain regions of the active regions, source/drain contacts disposed over source/drain features, and gate contact vias disposed over the gate structures. While these semiconductor structures may come in different shapes and dimensions in different regions of the substrate 100, they are fabricated using the same processes. The active regions may include silicon (Si), germanium (Ge), silicon germanium (SiGe). In some embodiments, the active regions may include a plurality of first semiconductor layers interleaved by a plurality of second semiconductor layers. The first semiconductor layers may be silicon (Si) layers and the second semiconductor layers may be silicon germanium (SiGe) layers. In the device region 102 where the semiconductor devices include MBC transistors, the silicon layers may become channel layers or channel members that may be released when the silicon germanium layers are selectively removed. In this sense, the silicon layers may be referred to as channel layers and the silicon germanium layers may be referred to as sacrificial layers. In the ring region 108 or the inner corner areas 106, the silicon germanium layers may not be selectively removed because the silicon germanium layers are not exposed when the dummy gate stacks are removed. For that reason, when the active regions include a stack of silicon layers interleaved by silicon germanium layers, the final structure in the ring region 108 may include active regions where both the silicon layer and the silicon germanium layers are present.

The gate structures include a gate dielectric layer and a gate electrode layer over the gate dielectric layer. In some embodiments, the gate dielectric layer includes an interfacial layer and a high-k gate dielectric layer. High-k dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-k gate dielectric layer may include hafnium oxide. Alternatively, the high-k gate dielectric layer may include other high-k dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-k gate dielectric layer may be formed by ALD, physical vapor deposition (PVD), CVD, oxidation, and/or other suitable methods.

The gate electrode layer may include a single layer or alternatively a multi-layer structure, such as various combinations of a metal layer with a selected work function to enhance the device performance (work function metal layer), an oxygen blocking layer, a capping layer, a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), molybdenum (Mo), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed using ALD, PVD, CVD, e-beam evaporation, or other suitable process.

Source/drain features may include silicon (Si) doped with an n-type dopant, such as phosphorus (P) or arsenic (As) or silicon germanium (SiGe) doped with a p-type dopant, such as boron (B) or boron difluoride (BF₂). The sourced/drain contacts may include a barrier layer, a silicide layer, and a metal fill layer disposed over the silicide layer. The barrier layer may include titanium nitride or tantalum nitride and functions to prevent electro-migration of the metal fill layer. The silicide layer may include titanium silicide, tantalum silicide, cobalt silicide, nickel silicide, or tungsten silicide. The silicide layer is disposed at the interface between the metal fill layer and the source/drain features to reduce contact resistance. The metal fill layer may include ruthenium (Ru), copper (Cu), nickel (Ni), cobalt (Co), or tungsten (W).

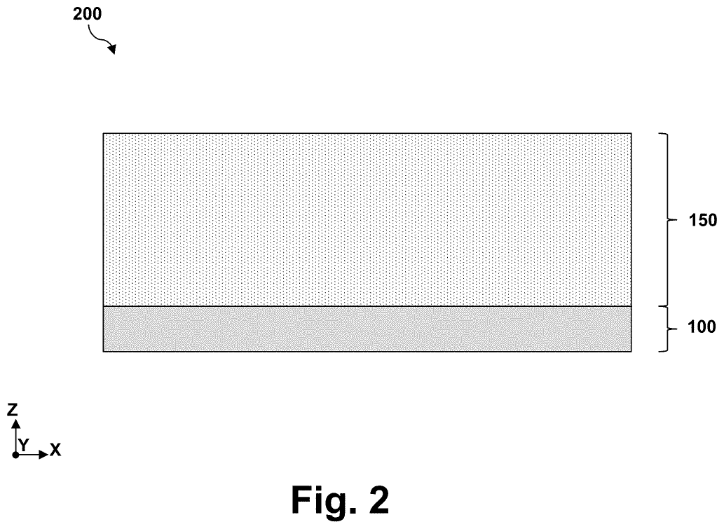

FIG. 2 illustrates a cross-sectional view of an interconnect structure 150 disposed on the substrate 100 in FIG. 1. The interconnect structure 150 may include more than 8 metal layers, such as between 9 metal layers and 14 metal layers. In one embodiment, the interconnect structure 150 includes 9 metal layers, which may include metal layers M0, M1, M2, M3, M4, M5, M6, M7, and M8. Each of the metal layers includes conductive lines embedded in an intermetal dielectric (IMD) layer. The interconnect structures 150 also includes contact vias that vertically interconnect conductive lines in different metal layers. The IMD layer may include materials such as tetraethylorthosilicate (TEOS) oxide, un-doped silicate glass, or doped silicon oxide, borophosphosilicate glass (BPSG), fused silica glass (FSG), phosphosilicate glass (PSG), boron doped silicon glass (BSG), silicon oxycarbide, and/or other suitable dielectric materials. The conductive lines and contact vias may include copper (Cu), titanium nitride (TiN), tungsten (W), or ruthenium (Ru). The interconnect structure 150 functionally connects transistors or semiconductor devices in the device region 102 of the substrate 100. The interconnect structure 150 and the substrate 100 may be collectively referred to as an integrated circuit (IC) chip 200.

The semiconductor structures in the substrate 100 form transistors, such as planar transistors or multi-gate transistors. Examples of multi-gate transistors may include fin-like field effect transistors (FinFETs) and multi-bridge-channel (MBC) transistors. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. When transistors in the substrate 100 are planar transistors, the active regions may include semiconductor features embedded in a dielectric layer. When transistors in the substrate 100 are FinFETs, the active regions may include fin-like semiconductor structures rising above an isolation feature and the gate structures are disposed over the fin-like semiconductor structures to engage two or three surfaces of the fin-like semiconductor structures. When transistors in the substrate 100 are MBC transistors, the active regions may each include a vertical stack of nanostructures and the gate structure wraps around each of nanostructures in the vertical stack of nanostructures. The nanostructures may have different cross-sections. In some instances, the nanostructures having a width substantially similar to its thickness may be referred to as nanowires. In some other instances, the nanostructures having a width greater than to its thickness may be referred to as nanosheets. MBC transistors may also be referred to as nanowire transistors or nanosheet transistors due to the shapes of the nanostructures.

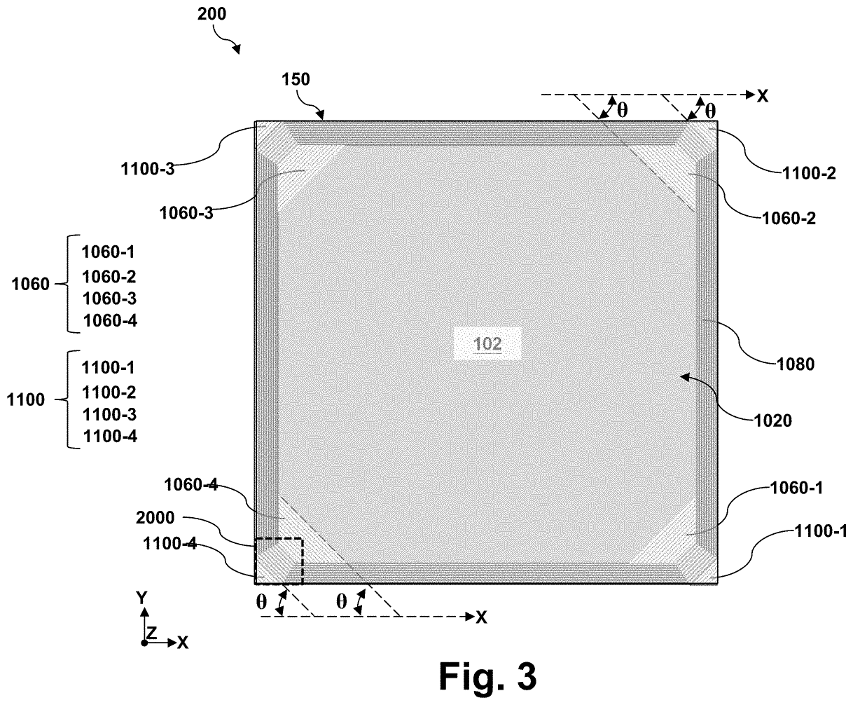

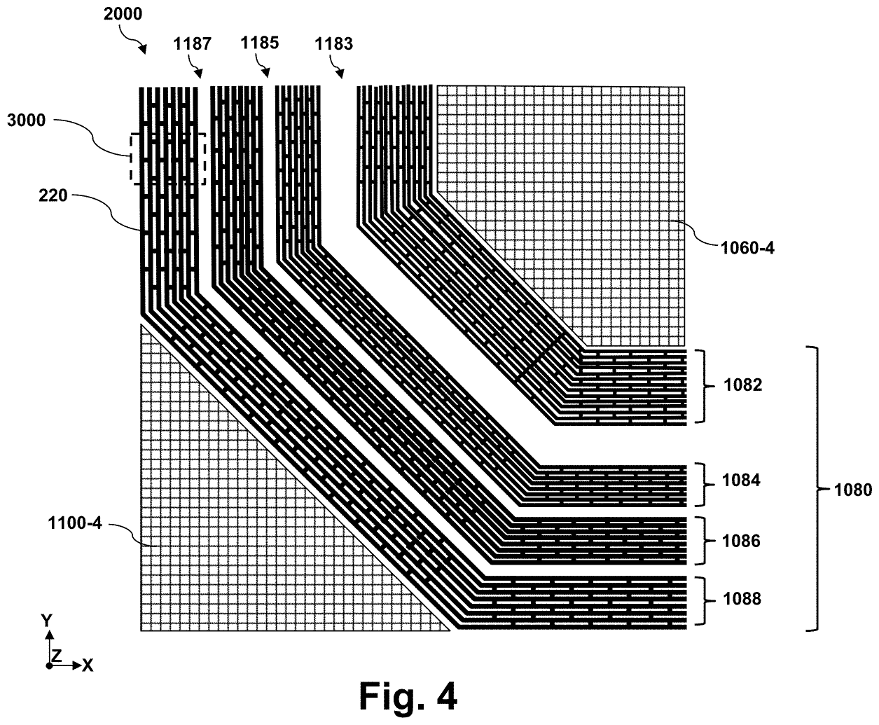

FIG. 3 illustrates a top view of the IC chip 200, which includes the substrate 100 and the interconnect structure 150 disposed on the substrate 100. As shown in FIG. 3, the interconnect structure 150 covers various regions of the substrate 100 and includes various portions vertically (i.e., along the Z direction) corresponding to various regions of the substrate 100. As shown in FIG. 3, the interconnect structure 150 includes a device portion 1020, inner corner portions 1060, a ring portion 1080, and outer corner portions 1100. In the depicted embodiments, the device portion 1020 is disposed directly over the device region 102, the inner corner portions 1060 are disposed directly over the inner corner areas 106, the ring portion 1080 is disposed directly over the ring region 108, and the outer corner portions 1100 are disposed directly over the outer corner areas 110. Like the inner corner areas 106, the inner corner portions 1060 include a first inner corner portion 1060-1, a second inner corner portion 1060-2, a third inner corner portion 1060-3, and a fourth inner corner portion 1060-4. Similar to the outer corner areas 110, the outer corner portions 1100 include a first outer corner portion 1100-1, a second outer corner portion 1100-2, a third outer corner portion 1100-3, and a fourth outer corner portion 1100-4. As shown in FIGS. 1 and 3, along the Z direction, the four inner corner areas 106 correspond to the four inner corner portions 1060 and the four outer corner areas 110 correspond to the four outer corner portions 1100. To illustrate various features of the present disclosure, a corner area 2000 of the interconnect structure will be enlarged and shown in FIG. 4.

FIG. 4 illustrates a fragmentary cross-sectional view of the corner area 2000 in FIG. 3. For ease of illustration, FIG. 4 only shows one of the lower metal layers of the interconnect structure 150 that are closer to the substrate 100. In some embodiments where the interconnect structure 150 includes 9 metal layers, the lower metal layers refer to the first five metal layers. In these embodiments, the first five metal layers include a first metal layer M0, a second metal layer M1, a third metal layer M2, a fourth metal layer M3, and a fourth metal layer M4. That is, FIG. 4 may be regarded as showing the first metal layer M0, the second metal layer M1, the third metal layer M2, the fourth metal layer M3, or the fifth metal layer M4. In some embodiments, the metal layers above the fifth metal layer M4 may have metal line widths much greater than those of the first five metal layers. In one embodiment, the metal line widths in the first five metal layers (i.e., M0-M4) are substantially below 1 μm while the metal line widths in the metal layers above the fifth metal layer M4 is above 1 μm. Experiments indicate that when the metal lines in a metal layer have a width greater than about 1 μm, such as between 1 μm and 2 μm, that metal layer tends to possess sufficient mechanical strength to withstand stress during the chip singulation process. However, when the metal line widths in a metal layer drop well below 1 μm, that metal layer may not have sufficient mechanical strength to withstand stress in the fabrication process.

Reference is still made to FIG. 4. The corner area 2000 includes the fourth outer corner portion 1100-4, a corner part of the ring portion 1080, and a corner part of the fourth inner corner portion 1060-4. The ring portion 1080 may include a plurality of seal ring walls that completely circle around the device portion 1020. In some embodiments represented in FIG. 4, the ring portion 1080 includes a first seal ring wall 1082, a second seal ring wall 1084, a third seal ring wall 1086, and a fourth seal ring wall 1088. Out of these four seal ring walls, the first seal ring wall 1082 is the innermost and the fourth seal ring wall 1088 is the outermost. When the ring portion 1080 is analogized to an octagonal racetrack, each of the seal ring walls may be analogized to a lane in the octagonal racetrack. The seal ring walls extend parallel to one another to go around the device portion 1020. As shown in FIG. 4, each of the first seal ring wall 1082, the second seal ring wall 1084, the third seal ring wall 1086, and the fourth seal ring wall 1088 includes a plurality of metal lines in each metal layer. In some instances, each of the seal ring walls may include between about 4 and about 20 metal lines in each metal layer. While the four seal ring walls extend parallel to one another, they are spaced apart by metal-free zones, where no metal lines or contact vias are embedded in intermetal dielectric (IMD) layers. In the depicted embodiments, the second seal ring wall 1084 is spaced apart from the first seal ring wall 1082 by a first metal-free zone 1183, the second seal ring wall 1084 is spaced apart from the third seal ring wall 1086 by a second metal-free zone 1185, the third seal ring wall 1086 is spaced apart from the fourth seal ring wall 1088 by a third metal-free zone 1187. The metal-free zones may have different width, measured between two adjacent seal ring walls.

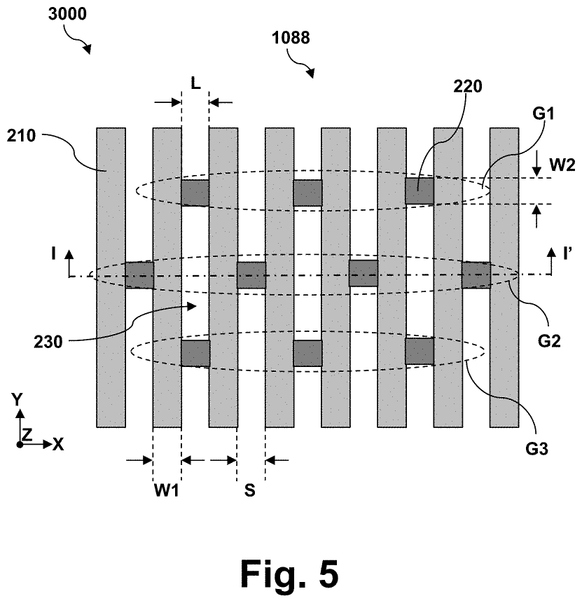

As described above, the metal line widths in the first five metal layers are substantially below 1 μm and may not possess sufficient mechanical strength. To reinforce metal lines in the first five metal layers in the ring portion 1080, lateral connectors 220 may be formed between two adjacent metal lines to improve the strength and stress absorption capabilities of the metal lines along the direction perpendicular to the longitudinal directions of the metal lines. To illustrate embodiments of the lateral connectors 220, an area 3000 in FIG. 4 will be enlarged and shown in FIG. 5.

Reference is now made to FIG. 5, which shows a top view of the area 3000 in FIG. 4. The area 3000 includes the fourth seal ring wall 1088 that extends vertically through the first five metal layers, including the first metal layer M0, the second metal layer M1, the third metal layer M2, the fourth metal layer M3, and the fifth metal layer M4. What is shown in FIG. 5 represents a portion of the fourth seal ring wall 1088 in one of the first five metal layers. In the metal layer shown in FIG. 5, the fourth seal ring wall 1088 includes a plurality of metal lines 210. In one embodiment, the fourth seal ring wall 1088 includes 8 metal lines in one metal layer. The plurality of metal lines 210 extend parallel to one another and go continuously around the device portion 1020. In the portion of the fourth seal ring wall 1088 shown in the area 300, the plurality of metal lines 210 extend along the Y direction.

The plurality of metal line 210, while being spaced apart from one another along the X direction in FIG. 5, are physically connected together along the X direction by a plurality of lateral connectors 220. In some implementations, the lateral connectors 220 are formed simultaneously with the plurality of metal lines 210. In an example process, trenches for the metal lines 210 and openings for the lateral connectors 220 are formed in an intermetal dielectric (IMD) layer using a combination of photolithography and etch techniques. Then the trenches and the openings are filled with a metal fill material or a combination of a barrier layer and a metal fill material layer. After a planarization process, such as a chemical mechanical polishing (CMP) process, the metal lines 210 and the lateral connectors 220 are formed in the IMD layer. The metal fill material may include aluminum (Al), copper (Cu), an aluminum/silicon/copper alloy, titanium (Ti), ruthenium (Ru), tungsten (W), a metal silicide, or combinations thereof. The barrier layer may include titanium nitride or tantalum nitride.

In some embodiments, the photolithographic radiation source to pattern features in the interconnect structure 150 has a wavelength of about 248 nm. To ensure that the features in the interconnect structures are well defined and have good line edge roughness (LER), the metal lines 210 may have a first width W1 between about 180 nm and about 250 nm and are spaced apart from one another by a spacing S between about 180 nm and about 250 nm, along the X direction. Because each of the lateral connectors 220 spans between two adjacent metal lines 210, the lateral connectors 220 have a length L between about 180 nm and about 250 nm along the X direction. In some embodiments, the lateral connectors 220 may be substantially square in shape. In these embodiments, the lateral connectors 220 may have a second width W2 along the Y direction and the second width W2 may be similar to the length L. As shown in FIG. 5, each of the lateral connectors 220 is only in contact with two adjacent metal lines 210. That is, none of the lateral connectors 220 may come in contact with more than two metal lines 210. The substantially square shape and the short length of the lateral connectors 220 make lateral connectors 220 resemble more to dots, rather than lines. Experiments show that patterning metal lines that are perpendicular to one another may reduce the resolution of the photolithography processes and increase line edge roughness (LER). In some instances, forming perpendicular metal lines may lead to defects and twisted lines.

Referring still to FIG. 5, the lateral connectors 220 are disposed between every other two adjacent metal lines 210. When the lateral connectors 220 extend every two adjacent metal lines 210 and are aligned, the lateral connectors 220 may appear as a continuous line that extends along a direction perpendicular to the metal lines 210, which, as described above, may lead to undesirable line patterns. In some embodiments represented in FIG. 5, the lateral connectors 220 come in groups. Three groups are shown in FIG. 5—a first group G1, a second group G2, and a third group G3. Each of the groups includes lateral connectors 220 that are spaced apart and aligned along a direction perpendicular to the longitudinal direction of the metal lines 210. In the depicted embodiment, the lateral connectors 220 in each of the groups are aligned along the X direction. Each of the groups may have different numbers of lateral connectors 220 when the seal ring wall includes an even number of metal lines 210. In the depicted embodiment, the fourth seal ring wall 1088 includes 8 metal lines, the first group G1 includes 3 lateral connectors 220, the second group G2 includes 4 lateral connectors, and the third group G3 includes 3 lateral connectors. Had the fourth seal ring wall 1088 includes 9 metal lines, the additional metal line would give the first group G1 and the third group G3 an additional lateral connector. Because the lateral connectors 220 in each group only extend between every other two adjacent metal lines 210, gaps 230 may be present between laterally connected metal lines 210. Gaps 230 are filled with IMD material but are free of any metal lines (i.e., 210-1 or 210-2) or lateral connectors 220. Each of the gaps 230, as shown in FIG. 5, is defined by two adjacent lateral connectors 220 and adjacent metal lines 210 on the X-Y plane parallel to the top surface of the substrate 100. In the depicted embodiments, each of groups are equally spaced along the longitudinal direction of the metal lines 210 to provide even mechanical reinforcement along the lengths of the metal lines 210. Because each of the metal lines 210 goes a full circle around the device portion 1020, each of the metal lines 210 may also be referred to as metal line loop. While not differentiated by reference numerals, it can be appreciated that outer metal line loops away from the device portion 1020 are larger than inner metal line loops closer to the device portion 1020. The seal ring walls and the metal line loops are illustrated in at least FIGS. 1, 3 and 4.

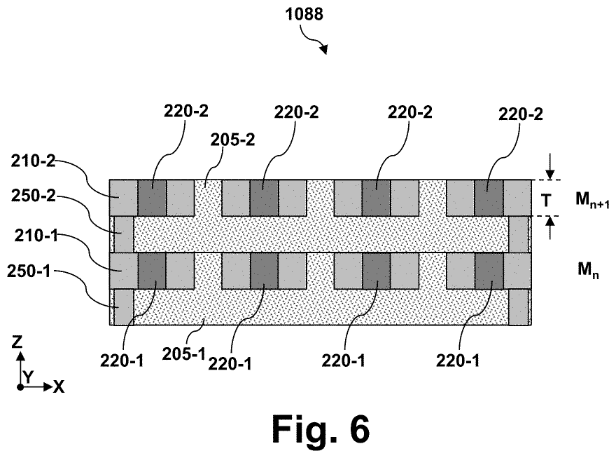

Reference is made to FIG. 6, which illustrates a cross-sectional view of the fourth seal ring wall 1088 along line I-I′ in FIG. 5. The cross-sectional view in FIG. 6 illustrates any two adjacent metal layers in the first five metal layers of the fourth seal ring wall 1088. In FIG. 6, the lower metal layer is labeled as Mₙ while the upper metal layer is labeled as Mₙ₊₁. In the denotation, n may be an integer between 0 and 3 such that Mₙ may represent any of the first four metal layers. In the embodiments represented in FIG. 6, the lateral connectors 220 are vertically aligned. In the cross-section along line I-I′, each of the lateral connectors 220-2 in the upper metal layer Mₙ₊₁ is vertically aligned with a lateral connector 220-1 in the lower metal layer Mₙ. As shown in FIG. 6, because the lateral connectors 220 and the metal lines 210-2 are formed simultaneously in the same processes, they share the same thickness T. In some embodiments, the thickness T may be between about 100 nm and about 300 nm. The cross-sectional view in FIG. 6 also shows that the outermost metal lines and innermost metal lines in two adjacent metal layers may be vertically connected by via bars, such as lower via bars 250-1 and upper via bars 250-2. Like the metal lines 210-1 and 210-2, the via bars 250-1 and 250-2 also extend continuously around the device portion 1020 to form closed loops. It can be seen that the closed-loop via bars and closed-loop outermost/innermost metal lines collectively form the inner wall surface and outer wall surface of the fourth seal ring wall 1088. In some embodiments not explicitly shown in FIG. 6, via bars may be implemented between the inner wall surface and outer wall surface for additional structural reinforcement. The gap-free seal ring walls help keep moisture out from the device portion 1020 and device region 102. Metal lines 210-1, lateral connectors 220-1 and lower via bars 250-1 in the lower metal layer Mₙ are disposed in a lower IMD layer 205-1. Metal lines 210-2, lateral connectors 220-2 and upper via bars 250-2 in the upper metal layer Mₙ₊₁ are disposed in an upper IMD layer 205-2.

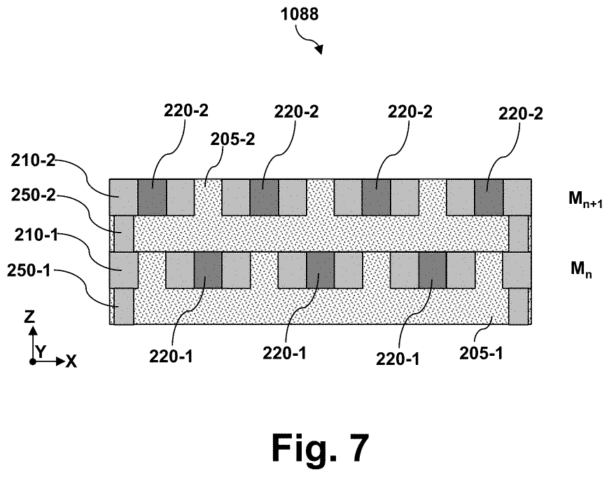

In some alternative embodiments represented in FIG. 7, the lateral connectors 220 are vertically misaligned. In the cross-section along line I-I′, each of the lateral connectors 220-2 in the upper metal layer Mₙ₊₁ is vertically misaligned with a lateral connector 220-1 in the lower metal layer Mₙ. The misalignment is resulted because the lateral connector 220-2 in the upper metal layer Mₙ₊₁ and the lateral connector 220-1 in the lower metal layer Mₙ are disposed between different sets of metal lines. In the depicted embodiment, the lateral connector 220-2 in the upper metal layer Mₙ₊₁ are disposed between the first metal line (from the left) and the second metal line, between the third metal line and the fourth metal line, between the fifth metal line and the sixth metal line, and between the seventh metal line and the eighth metal line while the lateral connectors 220-1 in the lower metal layer Mₙ are disposed between the second metal line (from the left) and the third metal line, between the fourth metal line and the fifth metal line, and between the sixth metal line and the seventh metal line. Other than the vertical relationship of the lateral connectors, FIGS. 6 and 7 share similar structures.

In some embodiments, the vertical alignment arrangement in FIG. 6 may permeate through the lower metal layers, such as the first five metal layers. In some other embodiments, the vertical alignment arrangement in FIG. 7 may permeate through the lower metal layers, such as the first five metal layers. In still some other embodiments, vertical alignment arrangements shown in FIGS. 6 and 7 may both be present in the first five metal layers. As described above, metal layers with metal line widths greater than about 1 μm may have sufficient mechanical strength to withstand stress in the fabrication process while the metal layers with metal line widths smaller than about 1 μm may not. In some embodiments, lateral connectors 220 may only be implemented in the metal layers that do not have sufficient mechanical but not in metal layers that do. In one embodiment, the first five metal layers have metal line widths below 1 μm but metal layers above the fifth metal layer have metal line widths above 1 μm. In these embodiments, lateral connectors 220 are only be implemented in the first five metal layers but not in the metal layers above the fifth metal layer.

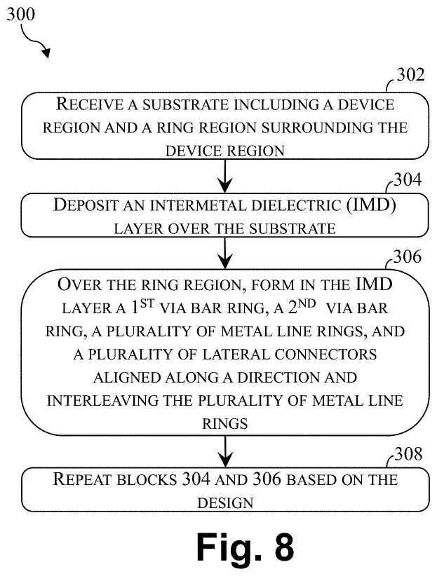

FIG. 8 provides a flowchart of a method 300 for fabricating an interconnect structure that includes multiple seal ring walls similar to the fourth seal ring wall 1088 shown in FIG. 6 or FIG. 7. The method 300 is merely an example and is not intended to limit the present disclosure to what is explicitly illustrated in the method 300. Additional steps can be provided before, during and after the method 100, and some steps described can be replaced, eliminated, or moved around for additional embodiments of the methods. Not all steps are described herein in detail for reasons of simplicity. Method 300 includes a block 302, a block 304, a block 306, and a block 308. At block 302, a substrate is provided. The substrate here may be similar to the substrate 100 shown in FIG. 1 and may include a device region similar to the device region 102 and a ring region similar to the ring region 108. As similarly illustrated in FIG. 1, the ring region completely surrounds the device region.

At block 304, an IMD layer, which is similar to the lower IMD layer 205-1 in FIG. 6 or 7, is blanketly deposited over the substrate 100. In some embodiments, the IMD layer may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In some instances, the IMD layer may be deposited using spin-on coating or flowable chemical vapor deposition (FCVD).

At block 306, a first via bar ring, a second via bar ring, a plurality of metal line rings, and a plurality of lateral connectors are formed in the IMD layer over the ring region. For illustration purposes, the first via bar ring and second via bar ring may be similar to the lower via bar 250-1 or the upper via bar 250-2 shown in FIG. 6 or 7. As the “ring” in their names suggests, each of the first via bar ring and the second via bar ring extends continuously around the device region. The first via bar ring and the second via bar ring help define a seal ring wall. For example, the first via bar ring may be closer to the device and the second via bar ring may be farther away from the device region. The plurality of metal line rings are similar to the metal line 210-1 shown in FIG. 6 or 7. The plurality of lateral connectors are similar to the lateral connectors 220-1 shown in FIG. 6 or 7. When the first via bar ring, the second via bar ring and the plurality of metal line rings extend along a first direction, the plurality of lateral connectors are aligned along a second direction perpendicular to the first direction. The alignment of the plurality of lateral connectors is illustrated in FIG. 5. The plurality of lateral connectors interleave the plurality of metal line rings as each of the plurality of lateral connectors physically couples to two adjacent metal line rings, hence their names. When dual damascene process is adopted, openings and trenches for the first via bar ring, the second via bar ring, the plurality of metal line rings, and the plurality of lateral connectors may be formed in the IMD layer using a combination of photolithography and etch processes. Then, a metal fill material, such as aluminum (Al), copper (Cu), an aluminum/silicon/copper alloy, titanium (Ti), ruthenium (Ru), tungsten (W), is deposited in the trenches and openings. As representatively shown in FIG. 6 or 7, the innermost metal line ring is substantially vertically aligned with the first via bar ring and the outermost metal line ring is substantially vertically aligned with the second via bar ring. Such vertical alignment helps define surfaces of a seal ring wall.

At block 308, operations at block 304 and block 306 are repeated for the number of metal layers according to the design. For example, when the interconnect structure includes 10 metal layers, operations at blocks 304 and 306 may be repeated 10 times. Depending on the design, lateral connectors in different metal layers may vertical overlap as shown in FIG. 6 or be offset as shown in FIG. 7.

In one exemplary aspect, the present disclosure is directed to an integrated circuit (IC) chip. The IC chip includes a substrate including a device region and a ring region surrounding the device region, and a first interconnect layer over the substrate and including a device portion disposed directly over the device region and a ring portion disposed directly over the ring region. The ring portion of the first interconnect layer includes a first metal line loop fully surrounding the device portion of the first interconnect layer, a second metal line loop fully surrounding the first metal line loop, a third metal line loop fully surrounding the second metal line loop, a fourth metal line loop fully surrounding the third metal line loop, a fifth metal line loop fully surrounding the fourth metal line loop, a first plurality of lateral connectors sandwiched between first metal line loop and the second metal line loop and between the third metal line loop and the fourth metal line loop, and a second plurality of lateral connectors sandwiched between the second metal line loop and the third metal line loop and between the fourth metal line loop and the fifth metal line loop.

In some embodiments, the first plurality of lateral connectors are aligned along a direction. In some embodiments, the second plurality of lateral connectors are aligned along the direction. In some implementations, the first metal line loop, the second metal line loop, the third metal line loop, the fourth metal line loop, the fifth metal line loop, the first plurality of lateral connectors, and the second plurality of lateral connectors are formed of the same material. In some instances, each of the first plurality of lateral connectors and the second plurality of lateral connectors is substantially square in shape when viewed in a top view. In some embodiments, the IC chip may further include a second interconnect layer over the first interconnect layer and including a device portion disposed directly over the device region and a ring portion disposed directly over the ring region. The ring portion of the second interconnect layer includes a sixth metal line loop fully surrounding the device portion of the second interconnect layer, a seventh metal line loop fully surrounding the sixth metal line loop, an eighth metal line loop fully surrounding the seventh metal line loop, a ninth metal line loop fully surrounding the eighth metal line loop, a tenth metal line loop fully surrounding the ninth metal line loop, a third plurality of lateral connectors sandwiched between sixth metal line loop and the seventh metal line loop and between the eighth metal line loop and the ninth metal line loop, and a fourth plurality of lateral connectors sandwiched between the seventh metal line loop and the eighth metal line loop and between the ninth metal line loop and the tenth metal line loop. In some embodiments, the third plurality of lateral connectors are disposed directly over the first plurality of lateral connectors. In some instances, the fourth plurality of lateral connectors are disposed directly over the second plurality of lateral connectors. In some instances, the third plurality of lateral connectors are not disposed directly over the first plurality of lateral connectors. In some embodiments, the fourth plurality of lateral connectors are not disposed directly over the second plurality of lateral connectors.

In another exemplary aspect, the present disclosure is directed to an IC chip. The IC chip includes a substrate including a device region and a ring region surrounding the device region, and an interconnect structure disposed over the substrate and including a device portion disposed directly over the device region and a ring portion disposed directly over the ring region. The ring portion of the interconnect structure includes a first group of metal layers and a second group of metal layers over the first group of metal layers. Each of the first group of metal layers includes a first plurality of metal line loops fully surrounding the device portion of the interconnect structure, and a plurality of lateral connectors sandwiched between two adjacent metal line loops of the first plurality of metal line loops. Each of the second group of metal layers includes a second plurality of metal line loops fully surrounding the device portion of the interconnect structure. Each of the second group of metal layers is free of any lateral connectors sandwiched between the second plurality of metal line loops.

In some embodiments, each of the first plurality of metal line loops has a width smaller than about 1 μm and each of the second plurality of metal line loops has a width greater than about 1 μm. In some implementations, none of the plurality of lateral connectors is in contact with more than two metal line loops of the first plurality of metal line loops. In some instances, each of the plurality of lateral connectors is substantially square in shape. In some embodiments, the first group of metal layers includes 5 metal layers. In some instances, the second group of metal layers includes 4 metal layers.

In yet another exemplary aspect, the present disclosure is directed to a method. The method includes receiving a substrate including a device region and a ring region surrounding the device region, depositing a dielectric layer over the substrate, and forming, in the dielectric layer over the ring region, a first via bar ring, a second via bar ring, a plurality of metal line rings over the first via bar ring and the second via bar ring, and a plurality of lateral connectors interleaving the plurality of metal line rings. The plurality of lateral connectors are aligned along a first direction.

In some embodiments, an innermost metal line ring is vertically aligned with the first via bar ring and an outermost metal line ring is vertically aligned with second via bar ring. In some implementations, each of the plurality of lateral connectors is sandwiched between two of the plurality of metal line rings along the first direction. In some instances, the first via bar ring, the second via bar ring, the plurality of metal line rings extend lengthwise along a second direction perpendicular to the first direction.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) chip, comprising:
a substrate including a device region and a ring region surrounding the device region; and
a first interconnect layer over the substrate and comprising a device portion disposed directly over the device region and a ring portion disposed directly over the ring region, the ring portion of the first interconnect layer comprising:
a first metal line loop fully surrounding the device portion of the first interconnect layer,
a second metal line loop fully surrounding the first metal line loop,
a third metal line loop fully surrounding the second metal line loop,
a fourth metal line loop fully surrounding the third metal line loop,
a fifth metal line loop fully surrounding the fourth metal line loop,
a first plurality of lateral connectors sandwiched between first metal line loop and the second metal line loop and between the third metal line loop and the fourth metal line loop, and
a second plurality of lateral connectors sandwiched between the second metal line loop and the third metal line loop and between the fourth metal line loop and the fifth metal line loop.

2. The IC chip of claim 1, wherein the first plurality of lateral connectors are aligned along a direction.

3. The IC chip of claim 2, wherein the second plurality of lateral connectors are aligned along the direction.

4. The IC chip of claim 1, wherein the first metal line loop, the second metal line loop, the third metal line loop, the fourth metal line loop, the fifth metal line loop, the first plurality of lateral connectors, and the second plurality of lateral connectors are formed of the same material.

5. The IC chip of claim 1, wherein each of the first plurality of lateral connectors and the second plurality of lateral connectors is substantially square in shape when viewed in a top view.

6. The IC chip of claim 1, further comprising:
a second interconnect layer over the first interconnect layer and comprising a device portion disposed directly over the device region and a ring portion disposed directly over the ring region, the ring portion of the second interconnect layer comprising:
a sixth metal line loop fully surrounding the device portion of the second interconnect layer,
a seventh metal line loop fully surrounding the sixth metal line loop,
an eighth metal line loop fully surrounding the seventh metal line loop,
a ninth metal line loop fully surrounding the eighth metal line loop,
a tenth metal line loop fully surrounding the ninth metal line loop,
a third plurality of lateral connectors sandwiched between sixth metal line loop and the seventh metal line loop and between the eighth metal line loop and the ninth metal line loop, and
a fourth plurality of lateral connectors sandwiched between the seventh metal line loop and the eighth metal line loop and between the ninth metal line loop and the tenth metal line loop.

7. The IC chip of claim 6, wherein the third plurality of lateral connectors are disposed directly over the first plurality of lateral connectors.

8. The IC chip of claim 6, wherein the fourth plurality of lateral connectors are disposed directly over the second plurality of lateral connectors.

9. The IC chip of claim 6, wherein the third plurality of lateral connectors are not disposed directly over the first plurality of lateral connectors.

10. The IC chip of claim 6, wherein the fourth plurality of lateral connectors are not disposed directly over the second plurality of lateral connectors.

11. An integrated circuit (IC) chip, comprising:
a substrate including a device region and a ring region surrounding the device region; and
an interconnect structure disposed over the substrate and comprising a device portion disposed directly over the device region and a ring portion disposed directly over the ring region, the ring portion of the interconnect structure comprising a first group of metal layers and a second group of metal layers over the first group of metal layers,
wherein each of the first group of metal layers comprises:
a first plurality of metal line loops fully surrounding the device portion of the interconnect structure, and
a plurality of lateral connectors sandwiched between two adjacent metal line loops of the first plurality of metal line loops,
wherein each of the second group of metal layers comprises a second plurality of metal line loops fully surrounding the device portion of the interconnect structure,
wherein each of the second group of metal layers is free of any lateral connectors sandwiched between the second plurality of metal line loops.

12. The IC chip of claim 11,
wherein each of the first plurality of metal line loops has a width smaller than about 1 μm,
wherein each of the second plurality of metal line loops has a width greater than about 1 μm.

13. The IC chip of claim 11, wherein none of the plurality of lateral connectors is in contact with more than two metal line loops of the first plurality of metal line loops.

14. The IC chip of claim 11, wherein each of the plurality of lateral connectors is substantially square in shape.

15. The IC chip of claim 11, wherein the first group of metal layers comprises 5 metal layers.

16. The IC chip of claim 11, wherein the second group of metal layers comprises 4 metal layers.

17. A method, comprising:
receiving a substrate comprising a device region and a ring region surrounding the device region;
depositing a dielectric layer over the substrate; and
forming, in the dielectric layer over the ring region:
a first via bar ring,
a second via bar ring,
a plurality of metal line rings over the first via bar ring and the second via bar ring, and
a plurality of lateral connectors interleaving the plurality of metal line rings,
wherein the plurality of lateral connectors are aligned along a first direction.

18. The method of claim 17,
wherein an innermost metal line ring is vertically aligned with the first via bar ring,
wherein an outermost metal line ring is vertically aligned with second via bar ring.

19. The method of claim 17, wherein each of the plurality of lateral connectors is sandwiched between two of the plurality of metal line rings along the first direction.

20. The method of claim 17, wherein the first via bar ring, the second via bar ring, the plurality of metal line rings extend lengthwise along a second direction perpendicular to the first direction.
